(19) United States
(12) Patent Application Publication
(10) Pub. No.: US 2026/0243729 A1
(43) Pub. Date: Aug. 20, 2026

(54) INTEGRATED MAGNETO-OPTICAL IMAGING PROBE AND PARAMETER SELF-ADJUSTING METHOD THEREOF

(71) Applicant: China University of Petroleum (East China), Qingdao City (CN)

(72) Inventors: Xiao LI, Qingdao City (CN); Wei LI, Qingdao City (CN); Jingchang QIN, Qingdao City (CN); Zhenqiang MOU, Qingdao City (CN); Ye YUAN, Qingdao City (CN); Youshun HOU, Qingdao City (CN); Xin'an YUAN, Qingdao City (CN)

(21) Appl. No.: 19/370,220

(22) Filed: Oct. 27, 2025

(30) Foreign Application Priority Data
Feb. 19, 2025 (CN) 202510183433.3

(51) Int. Cl. G01N 27/87; G01R 33/00; G01R 33/032

(52) U.S. Cl. CPC G01N 27/87; G01R 33/0035; G01R 33/032

(57) ABSTRACT

An integrated magneto-optical imaging probe and a parameter self-adjusting method thereof are provided. The integrated magneto-optical imaging probe has a vertical “projection-collection” optical path and a smaller sensing gap, and has a higher defect imaging definition and an integrated layout of device. A parameter self-adjusting method of an integrated magneto-optical imaging probe is provided and includes the following steps: obtaining a maximum leakage magnetic field intensity at the defect of a workpiece to be tested; constructing a three-dimensional simulation model of the integrated magneto-optical imaging probe; setting an optical physical field for a geometric structure of each part of the three-dimensional simulation model; performing differential meshing on the three-dimensional simulation model; setting scanning parameters for the three-dimensional simulation model, and calculating a value of each variable in the three-dimensional simulation model; and drawing a simulated magneto-optical image.

### CROSS-REFERENCE TO RELATED PRESENT DISCLOSURE

This patent application claims the benefit and priority of Chinese Patent Application No. 202510183433.3 filed with the China National Intellectual Property Administration on Feb. 19, 2025, the disclosure of which is incorporated by reference herein in its entirety as part of the application.

### TECHNICAL FIELD

The present disclosure belongs to the technical field of the detection of oil and gas device, and in particular to an integrated magneto-optical imaging probe and a parameter self-adjusting method thereof.

### BACKGROUND

As important devices in the oil and gas field, an oil and gas pipeline and a storage tank play an indispensable role in the process of transporting, transferring and storing oil and gas. The inventor finds that the working environment of the foregoing devices is harsh, and the device is easily affected by factors, such as mechanical impact and medium corrosion, resulting in defects, such as cracks, deformation, and corrosion. It is required technicians to regularly detect and maintain the devices, so as to implement effective intervention measures before the accident and avoid causing major economic losses and casualties.

The existing methods for detecting oil and gas devices mainly include the following types: a ray method, an eddy current method, an ultrasonic method, a magnetic leakage method, and the like. However, after further research, it is found that the existing methods for detecting oil and gas devices have a series of limitations, such as low efficiency, insufficient sensitivity and poor visibility. Moreover, the detection process relies more on manual experience, resulting in poor stability of the detection results. Therefore, it is urgent for technicians in this field to develop a detection device with a high imaging definition, a high integration, and an intelligent parameter adjusting function, thus providing a reliable technical support for defect detection of oil and gas devices.

### SUMMARY

The present disclosure provides an integrated magneto-optical imaging probe and a parameter self-adjusting method thereof. The integrated magneto-optical imaging probe has a vertical “projection-collection” optical path and a smaller sensing gap, and has a higher defect imaging definition and an integrated layout of device. In addition, a parameter self-adjusting method of a probe is provided, which can adapt to detection requirements of diversified working conditions and effectively improve adaptability of the probe.

In order to solve the foregoing technical problems, the present disclosure uses the following technical solution:
an integrated magneto-optical imaging probe, where the integrated magneto-optical imaging probe includes a linearly polarized light emitting unit, a linearly polarized light modulation unit, a linearly polarized light imaging unit, and a clamping mechanism;
the clamping mechanism comprising an inner shell and an outer shell; wherein a linearly polarized light path is formed between the inner shell and the outer shell;
the linearly polarized light emitting unit comprising a light-emitting diode (LED) light source, a light guide plate, and a polarizer; wherein the LED light source is fixedly installed on a side wall of the inner shell; the light guide plate is fixedly installed inside the inner shell, and is configured to modulate light output by the LED light source into parallel light in a horizontal direction; and the polarizer is fixedly installed inside the inner shell and is arranged perpendicular to the parallel light, and is configured to modulate the parallel light into linearly polarize light;
the linearly polarized light modulation unit comprising a magneto-optical sensing module, a beam splitter, a silicon steel yoke, and a neodymium magnet; wherein the magneto-optical sensing module is fixedly installed inside the inner shell directly below the linearly polarized light path; the beam splitter is fixedly installed inside the inner shell and is configured to reflect the linearly polarized light modulated by the polarizer to a position of the magneto-optical sensing module; and the neodymium magnet and the silicon steel yoke are sequentially arranged and installed on a periphery of the linearly polarized light path to form a closed magnetic field loop; and
the linearly polarized light imaging unit comprising a camera, an analyzer, a camera driving board, and a Lemo connector; wherein the analyzer is fixedly installed on a top of the outer shell directly above the linearly polarized light path, and is configured to receive the linearly polarized light modulated by a leakage magnetic field; the camera, the camera driving board, and the Lemo connector are sequentially connected with the analyzer to convert an optical signal captured by the analyzer into an electrical signal and transmit the electrical signal to an external display device.

In some embodiments, the magneto-optical sensing module comprises a magneto-optical film, a mirror plating, and a protective coating; wherein the magneto-optical film is configured to induce a magneto-optical rotation effect in the linearly polarized light, the mirror plating is configured to reflect the linearly polarized light, and the protective coating is configured to protect the magneto-optical film and the mirror plating.

On the other hand, the present disclosure further provides a parameter self-adjusting method of an integrated magneto-optical imaging probe, including the following steps:
Step 1, obtaining a maximum leakage magnetic field intensity at a defect of a workpiece to be tested;
Step 2, constructing a three-dimensional simulation model of the integrated magneto-optical imaging probe;
Step 3, setting an optical physical field for a geometric structure of each part of the three-dimensional simulation model constructed in step 2;
Step 4, performing differential meshing on the three-dimensional simulation model processed in step 3; and
Step 5, setting scanning parameters for the three-dimensional simulation model processed in step 4, and calculating a value of each variable in the three-dimensional simulation model; and drawing a simulated magneto-optical image.

In some embodiments, the parameter self-adjusting method of the integrated magneto-optical imaging probe further includes the following steps:
Step 6, analyzing the simulated magneto-optical image obtained in step 5, and determining an optimal value of each variable in the three-dimensional simulation model.

In some embodiments, step 1 is specifically described as:
placing the integrated magneto-optical imaging probe directly above the defect of the workpiece to be tested to excite the leakage magnetic field; and
using a Tesla meter to measure the maximum leakage magnetic field intensity B at the defect of the workpiece to be tested.

In some embodiments, step 2 is specifically described as:
using a COMSOL model builder to construct the three-dimensional simulation model of the integrated magneto-optical imaging probe, wherein the three-dimensional simulation model constructed at least comprises simulation of geometrically simplified structures of the LED light source, the polarizer, a magneto-optical film, a mirror plating, the beam splitter, the camera, the analyzer, and a light blocking surface.

In some embodiments, step 3 is specifically described as:
setting the LED light source to emit uniform unpolarized light based on a mesh unit, in which a light source power set to W and an emitted light intensity I₀ satisfy:

$${I}_{0} = \frac{W}{l \times b} ; \qquad ( 1 )$$

in the Formula (1), l and b are the length and the width of the light emitting surface of the LED light source, respectively;
setting the polarizer, the magneto-optical film, and the analyzer as linear polarizers, wherein a transmission axis of the polarizer is defined as vₚ=(vₚₓ, v_{py}, v_{pz})=(cₚ, cₚ tan γ, 0) (2);
in formula (2), vₚ is a direction vector of the transmission axis of the polarizer, vₚₓ, v_{py}, and v_{pz} are projections of vₚ on an x-axis, a y-axis, and a z-axis, respectively, cₚ is a constant, and y is an included angle between vₚ and a horizontal direction; and after the parallel light passes through the polarizer, a light intensity of the parallel light becomes I₀/2;
a deflection angle θ at which the linearly polarized light deflects when passing through the magneto-optical film satisfying: θ=VBT (3);
in formula (3), Vis Verdet constant, and Tis a thickness of the magneto-optical film;
a transmission axis of the magneto-optical film is defined as

$${v}_{m} = ( {v}_{m x} , {v}_{m y} , {v}_{m z} ) = ( {c}_{m} , {c}_{m} tan ( γ + θ ) , 0 ) = ( {c}_{m} , {c}_{m} tan ( γ + VBT ) , 0 ) ; \qquad ( 4 )$$

in formula (4), vₘ is a direction vector of the transmission axis of the magneto-optical film, vₘₓ, v_{my}, and v_{mz} are projections of vₘ on the x-axis, the y-axis, and the z-axis, respectively, and cₘ is a constant; and
a transmission axis of the analyzer is defined as

$${v}_{d} = ( {v}_{dx} , {v}_{dy} , {v}_{d z} ) = ( {c}_{d} , {c}_{d} tan ( γ + VBT + α ) , 0 ) ; \qquad ( 5 )$$

in formula (5), v_{d} is a direction vector of the transmission axis of the analyzer, v_{dx}, v_{dy}, and v_{dz} are projections of v_{d} on the x-axis, the y-axis, and the z-axis, respectively, and c_{d} is a constant; and
setting a reflectivity of the beam splitter to r, setting a transmissivity of the beam splitter to 1−r, setting a reflection coefficient of the mirror plating to 1, and a light intensity I_{D} of the linearly polarized light after passing through the analyzer satisfying:

$${I}_{D} = 0.5 r ( 1 - r ) {I}_{0} {cos}^{2} ( VBT + α ) = 0.5 r ( 1 - r ) \frac{W}{l \times b} {cos}^{2} ( VBT + α ) . \qquad ( 6 )$$

In some embodiments, Step 6 is specifically described as:
calculating an average gray level Gave of the simulated magneto-optical image, a maximum gray level Gₘₐₓ of the simulated magneto-optical image, and a minimum gray level Gₘᵢₙ of the simulated magneto-optical diagram;
where the average gray level Gₐᵥₑ of the simulated magneto-optical image satisfies:

$${G}_{a v e} = \frac{1}{M \times N} {\sum }_{i = 1}^{M} {\sum }_{j = 1}^{N} I ( i , j ) ; \qquad ( 8 )$$

in the Formula (8), M and N denote the height and the width of the simulated magneto-optical image, respectively, and I(i, j) denotes the gray level of the pixel point (i, j);
the maximum gray level Gₘₐₓ of the simulated magneto-optical image satisfies:

$${G}_{ma x} = {max}_{1 \leq i \leq M , 1 \leq j \leq N} I ( i , j ) ; \qquad ( 9 )$$

the minimum gray level Gₘᵢₙ of the simulated magneto-optical image satisfies:

$${G}_{m i n} = {min}_{1 \leq i \leq M , 1 \leq j \leq N} I ( i , j ) ; \qquad ( 10 )$$

constructing an evaluation function E; where the evaluation function E satisfies:

$$E = \frac{{G}_{m ax} - {G}_{m i n}}{{G}_{a v e}} ; \qquad ( 11 )$$

and
calculating a value of E under different variable conditions; in which when the value of E is a maximum, a value of each variable in the three-dimensional simulation model corresponding to the maximum is the optimal value.

The present disclosure provides an integrated magneto-optical imaging probe and a parameter self-adjusting method thereof, where the parameter self-adjusting method includes the following steps: Step 1, obtaining a maximum leakage magnetic field intensity at the defect of a workpiece to be tested; Step 2, constructing a three-dimensional simulation model of the integrated magneto-optical imaging probe; Step 3, setting an optical physical field for a geometric structure of each part of the three-dimensional simulation model constructed in Step 2; Step 4, performing differential meshing on the three-dimensional simulation model processed in Step 3; and Step 5, setting scanning parameters for the three-dimensional simulation model processed in Step 4, and calculating a value of each variable in the three-dimensional simulation model; and drawing a simulated magneto-optical image.

The integrated magneto-optical imaging probe with the above technical features and the parameter self-adjusting method thereof have a vertical “projection-collection” optical path and a smaller sensing gap, and therefore, have a higher defect imaging definition and an integrated layout of device. At the same time, the present disclosure further provides a parameter self-adjusting method of a probe, which can adapt to detection requirements of diversified working conditions. Compared with the prior art, the technical solution of the present disclosure at least has the following technical advantages.
(1) The device structure has a higher integration and less out-of-focus phenomenon, which can effectively improve the definition of defect detection imaging.
(2) The device makes up the deficiency of experiment-based parameter adjustment in the prior art, improves applicability of the integrated magneto-optical imaging probe, and allows the integrated magneto-optical imaging probe to adapt to different working conditions through precise parameter adjustment.

### BRIEF DESCRIPTION OF THE DRAWINGS

The accompanying drawings are provided to provide a further understanding of the present disclosure and constitute a part of the specification. The accompanying drawings, together with the embodiments of the present disclosure, serve to explain the present disclosure, and do not constitute a limitation of the present disclosure. In the following accompanying drawings:

FIG. 1 is a schematic structural diagram of an integrated magneto-optical imaging probe according to the present disclosure;

FIG. 2 is a schematic structural diagram of a magneto-optical sensing module;

FIG. 3 is a schematic flow chart of a parameter self-adjusting method of an integrated magneto-optical imaging probe according to the present disclosure; and

FIG. 4 is a schematic diagram of a three-dimensional simulation model of an integrated magneto-optical imaging probe constructed by a parameter self-adjusting method of an integrated magneto-optical imaging probe.

### REFERENCE NUMERALS

1, led light source; 2, light guide plate; 3, polarizer; 4, pet tape; 5, magneto-optical sensing module; 501, magneto-optical film; 502, mirror plating; 503, protective coating; 6, beam splitter; 7, inner shell; 8, silicon steel yoke; 9, neodymium magnet; 10, camera; 11, analyzer; 12, camera driving board; 13, Lemo connector; 14, outer shell.

### DETAILED DESCRIPTION OF THE EMBODIMENTS

The present disclosure provides an integrated magneto-optical imaging probe and a parameter self-adjusting method thereof. The integrated magneto-optical imaging probe has a vertical “projection-collection” optical path and a small sensing gap, and has a higher defect imaging definition and an integrated layout of device. In addition, a parameter self-adjusting method of a probe is provided, which can adapt to detection requirements of diversified working conditions and effectively improve adaptability of the probe.

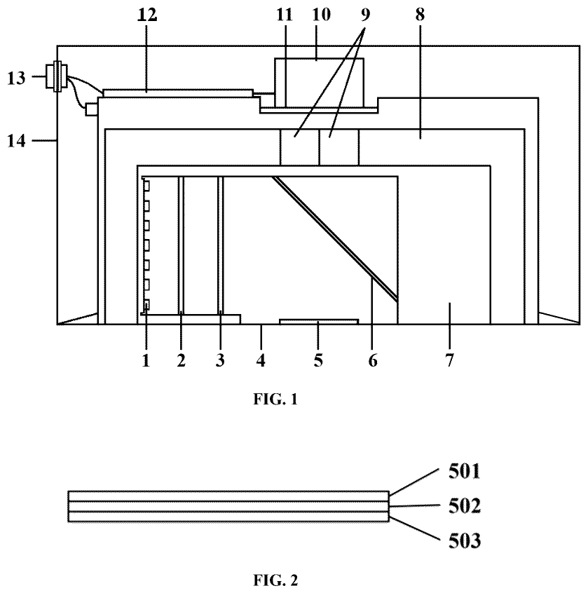

The present disclosure provides an integrated magneto-optical imaging probe. As shown in FIG. 1, the integrated magneto-optical imaging probe includes a linearly polarized light emitting unit, a linearly polarized light modulation unit, a linearly polarized light imaging unit, and a clamping mechanism.

Specifically, the clamping mechanism consists of an inner shell 7 and an outer shell 14. It is worth noting that, the inner shell 7 is configured to provide installation space for a structural unit such as an LED light source 1, a light guide plate 2, a polarizer 3, a magneto-optical sensing module 5, and a beam splitter 6. The outer shell 14 is configured to provide installation space for a structural unit such as a camera 10, an analyzer 11, and a camera driving board 12. In addition, a linearly polarized light path is formed between the inner shell 7 and the outer shell 14.

The linearly polarized light emitting unit includes an LED light source 1, a light guide plate 2, and a polarizer 3. The LED light source 1 is fixedly installed on a side wall of the inner shell 7 and is configured to provide a natural light source. In this embodiment, the selected LED light source 1 outputs green natural light with a wavelength of 520 to 530 nm, is provided with a light emitting surface with a size of 15 mm×15 mm, and has a power W determined according to different light source models. The light guide plate 2 is fixedly installed inside the inner shell 7, and is configured to modulate light output by the LED light source 1 into parallel light in a horizontal direction. The polarizer 3 is fixedly installed inside the inner shell 7 and is arranged in a direction perpendicular to the parallel light (by screening specific polarization components in parallel natural light), and is configured to modulate the parallel light into linearly polarize light.

The linearly polarized light modulation unit includes a magneto-optical sensing module 5, a beam splitter 6, a silicon steel yoke 8, and a neodymium magnet 9. The beam splitter 6 is fixedly installed inside the inner shell 7, and is configured to reflect the linearly polarized light modulated by the polarizer 3 to a position of the magneto-optical sensing module 5. The magneto-optical sensing module 5 is fixedly installed inside the inner shell 7 directly below the linearly polarized light path via a PET tape 4.

As a preferred embodiment of the present disclosure, as shown in FIG. 2, the magneto-optical sensing module 5 consists of a magneto-optical film 501, a mirror plating 502, and a protective coating 503. The magneto-optical film 501 (the thickness T of the magneto-optical film is selected to be 0.05 mm, and the Verdet constant Vis 1.04×10⁶ rad/mT) is configured to induce a magneto-optical rotation effect in the linearly polarized light. The mirror plating 502 is configured to reflect the linearly polarized light. The protective coating 503 is configured to protect the magneto-optical film 501 and the mirror plating 502.

In addition, the neodymium magnet 9 and the silicon steel yoke 8 are sequentially arranged and installed on a periphery of the linearly polarized light path. The silicon steel yoke 8 and the neodymium magnet 9 are configured to form a closed magnetic field loop, thereby generating a leakage magnetic field at (directly above) the defect of the workpiece to be tested.

The linearly polarized light imaging unit includes a camera 10, an analyzer 11, a camera driving board 12, and a Lemo connector 13. The analyzer 11 is fixedly installed on the top of the outer shell 14 directly above the linearly polarized light path, and is configured to receive the linearly polarized light modulated by the leakage magnetic field. The camera 10 (the performance parameters of the camera may be referred to as follows: 1280×720 pixels, the frame rate of 120 frames per second (FPS), the pixel size of 3 m×3 m, the lens focal length of 12 mm, and the external dimension of 8 mm×8 mm×5 mm), the camera driving board 12, and the Lemo connector 13 are sequentially connected with the analyzer 11 to convert an optical signal captured by the analyzer 11 into an electrical signal and transmit the electrical signal to an external display device.

It is worth noting that the linearly polarized light modulated by the leakage magnetic field may be used to reflect the defect of the workpiece to be tested. Therefore, through the analysis of the output electrical signal, the specific defect of the workpiece to be tested can be finally determined.

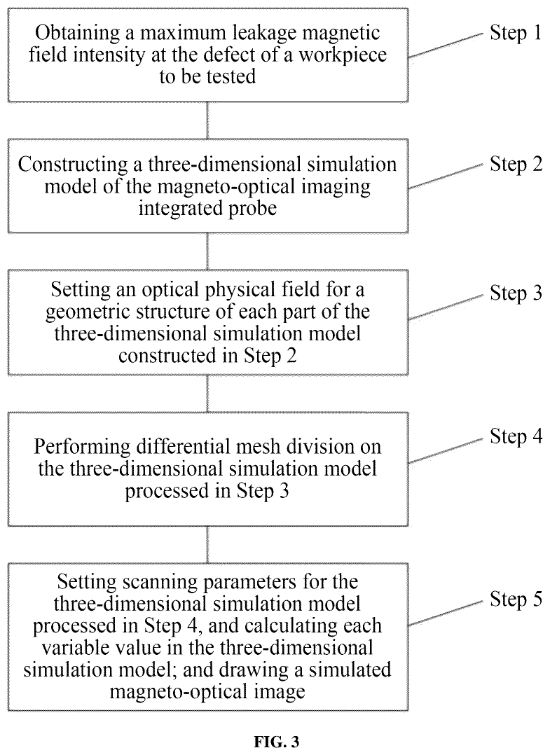

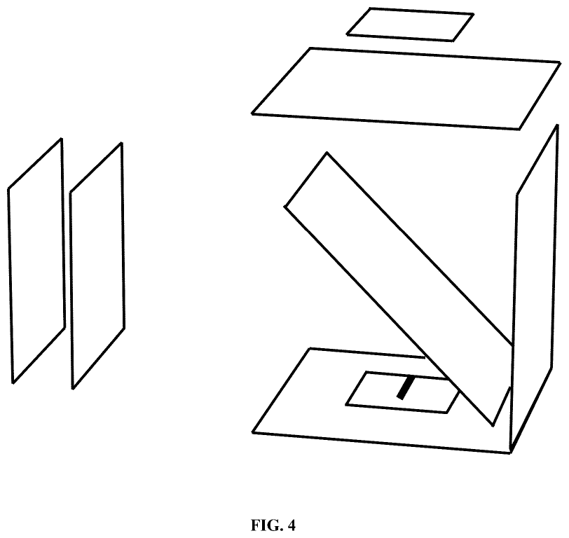

On the other hand, the present disclosure further provides a parameter self-adjusting method of an integrated magneto-optical imaging probe. As shown in FIG. 3, the parameter self-adjusting method of the integrated magneto-optical imaging probe specifically includes the following steps.
Step 1, a maximum leakage magnetic field intensity at the defect of a workpiece to be tested is obtained.

As a preferred embodiment of the present disclosure, Step 1 may be specifically described as follows:
placing the integrated magneto-optical imaging probe directly above the defect of the workpiece to be tested to excite a leakage magnetic field; and
using a Tesla meter to measure the maximum leakage magnetic field intensity B at the defect of the workpiece to be tested.
Step 2, a three-dimensional simulation model of the integrated magneto-optical imaging probe is constructed.

On the basis of completing Step 1, the three-dimensional simulation model of the integrated magneto-optical imaging probe is further constructed. As a preferred embodiment of the present disclosure, Step 2 may be specifically described as follows:
using a COMSOL model builder, and using a specific interface between a three-dimensional space dimension and an optical physical field to construct the three-dimensional simulation model of the integrated magneto-optical imaging probe. It is worth noting that the constructed three-dimensional simulation model at least includes simulation of geometrically simplified structures of the light-emitting diode (LED) light source 1, the polarizer 3, the magneto-optical film 501, the mirror plating 502, the beam splitter 6, the camera 10, the analyzer 11, and a light blocking surface, as shown in FIG. 4 for details.
Step 3, an optical physical field is set for a geometric structure of each part of the three-dimensional simulation model constructed in Step 2.

On the basis of completing Step 2, further, the optical physical field is set for the geometric structure of each part of the three-dimensional simulation model. As a preferred embodiment of the present disclosure, Step 3 mainly sets the optical physical field for the geometric structures of the LED light source 1, the polarizer 3, the magneto-optical film 501, and the analyzer 11, and describes the beam splitter 6, the camera 10, and the light blocking surface in a simplified manner.

First, the LED light source 1 is set to emit uniform unpolarized light based on a mesh unit, in which a light source power of the uniform unpolarized light set to W and an emitted light intensity I₀ satisfy:

$${I}_{0} = \frac{W}{l \times b} . \qquad ( 1 )$$

In the Formula (1), l and b are the length and the width of the light emitting surface of the LED light source 1, respectively.

Specifically, selection is made according to the design of the integrated magneto-optical imaging probe, that is, l=b=15 mm. Therefore, the Formula (1) obtains the emitted light intensity

$${I}_{0} = \frac{W}{2.25 \times 1 {0}^{- 4}} W / {m}^{2} .$$

Then, the polarizer 3, the magneto-optical film 501, and the analyzer 11 are set as linear polarizers.

The transmission axis of the polarizer 3 is defined as vₚ=(vₚₓ, v_{py}, v_{pz})=(cₚ, cₚ tan γ, 0) (2);
in the Formula (2), vₚ is a direction vector of the transmission axis of the polarizer 3, vₚₓ, v_{py}, and v_{pz} are projections of vₚ on the x-axis, the y-axis, and the z-axis, respectively, cₚ is a constant, and y is an included angle between vₚ and a horizontal direction; and after the parallel light passes through the polarizer 3, a light intensity of the parallel light becomes I₀/2.

A deflection angle θ at which the linearly polarized light deflects when passing through the magneto-optical film 501 satisfies: θ=VBT (3);
in the Formula (3), V is the Verdet constant, and Tis the thickness of the magneto-optical film 501.

It should be added that, because the light transmission axis of the polarizer 3 is set in the horizontal direction to satisfy γ=0, the direction vector obtained by the Formula (2) is vₚ=(1,0,0), and the rotation angle of the Formula (3) satisfies θ=2600 Brad, where B is the maximum leakage magnetic field intensity B at the defect of the workpiece to be tested measured by the Tesla meter in Step 1.

The transmission axis of the magneto-optical film 501 is defined as

$${v}_{m} = ( {v}_{m x} , {v}_{m y} , {v}_{m z} ) = ( {c}_{m} , {c}_{m} tan ( γ + θ ) , 0 ) = ( {c}_{m} , {c}_{m} tan ( γ + VBT ) , 0 ) ; \qquad ( 4 )$$

in the Formula (4), vₘ is a direction vector of the transmission axis of the magneto-optical film 501, vₘₓ, v_{my}, and v_{mz} are projections of vₘ on the x-axis, the y-axis, and the z-axis, respectively, and cₘ is a constant.

By substituting the foregoing calculated values, the direction vector calculated from the Formula (4) is: vₘ=(cos(2600 B), sin(2600 B),0).

The transmission axis of the analyzer 11 is defined as v_{d}=(v_{dx},v_{dy},v_{dz})=(c_{d},c_{d} tan(γ+VBT+α),0) (5);
in the Formula (5), Va is a direction vector of the transmission axis of the analyzer 11, v_{dx}, v_{dy}, and v_{dz} are projections of v_{d} on the x-axis, the y-axis, and the z-axis, respectively, and c_{d} is a constant. α is an included angle between the transmission axis of the polarizer 3 and the transmission axis of the analyzer 11.

By substituting the foregoing calculated values, the direction vector calculated from the Formula (5) is: v_{d}=(cos(2600 B+α),sin(2600 B+α),0).

Further, the reflectivity of the beam splitter 6 is set to r, the transmissivity of the beam splitter 6 is set to 1−r, the reflection coefficient of the mirror plating 502 is set to 1, and the light intensity I_{D} of the linearly polarized light after passing through the analyzer 11 satisfies:

$${I}_{D} = 0.5 r ( 1 - r ) {I}_{0} {cos}^{2} ( V B T + α ) = 0.5 r ( 1 - r ) \frac{W}{l \times b} {cos}^{2} ( V B T + α ) . \qquad ( 6 )$$

By substituting the foregoing calculated values, it can be known that the light intensity calculated from the Formula (6) satisfies:

$${I}_{D} = \frac{W r ( 1 - r )}{4.5 \times 1 {0}^{- 4}} {cos}^{2} ( 2600 B + α ) W / {m}^{2} .$$

Finally, the wall condition of the light blocking surface is set to disappear, thereby deleting the redundant light reflected and transmitted by the beam splitter 6 (for the purpose of saving computational power). Then, the wall condition of the camera 10 is set to freeze, thereby ensuring that the camera 10 can capture and save the position and intensity information of the corresponding linearly polarized light.
Step 4, differential meshing is performed on the three-dimensional simulation model processed in Step 3.

On the basis of completing Step 3, further, differential meshing is performed on the three-dimensional simulation model. Specifically, in order to ensure the accuracy of simulation and a relatively fast operation speed for the calculation process, here, a smaller cell mesh (for example, the side length of the mesh unit of the cell mesh is set to 0. 01 mm) is set for the light source 1, the magneto-optical film 501, and the camera 10, which require high calculation accuracy; and a larger cell mesh (for example, the side length of the mesh unit of the cell mesh is set to 0.05 mm) may be optionally set for other structures that do not require high calculation accuracy.
Step 5, scanning parameters are set for the three-dimensional simulation model processed in Step 4, and a value of each variable in the three-dimensional simulation model are calculated; and a simulated magneto-optical image is drawn.

On the basis of completing Step 4, further, the three-dimensional simulation model is further calculated and solved in order to draw the simulated magneto-optical image. It is worth noting that in order to solve the variables W, a, and r, which are important influence for the imaging effect, the scanning parameters are set for the three-dimensional simulation model first, so as to assign values to the above variables.

The specific variables satisfy:

$$\{ \begin{matrix}W = range ( {i}_{w} , {s}_{w} , {f}_{w} ) \\ α = range ( {i}_{α} , {s}_{α} , {f}_{α} ) \\ r = range ( {i}_{r} , {s}_{r} , {f}_{r} )\end{matrix} ; \qquad ( 7 )$$

where the range is the name of a built-in function of COMSOL, i_{w}, s_{w}, and f_{w} are the initial value, the step size, and the final value of the variable W; i_{α}, s_{α} and f_{α} are the initial value, the step size, and the final value of variable α; and iᵣ, sᵣ and fᵣ are the initial value, the step size, and the final value of variable r, respectively. The foregoing three variables are substituted into the Formula (6), and the solver of the three-dimensional simulation model is called for calculation, so as to draw the simulated magneto-optical image of the camera 10 when W, α, and r take corresponding values.

Further, a parameter self-adjusting method of an integrated magneto-optical imaging probe provided by the present disclosure further includes the following step:
Step 6, the simulated magneto-optical image obtained in Step 5 is analyzed, and an optimal value of each variable in the three-dimensional simulation model is determined.

On the basis of completing Step 5, further, the simulated magneto-optical image is analyzed. As a preferred embodiment of the present disclosure, Step 6 is specifically described as:
first, calculating the average gray level Gₐᵥₑ of the simulated magneto-optical image, the maximum gray level Gₘₐₓ of the simulated magneto-optical image, and the minimum gray level Gₘᵢₙ of the simulated magneto-optical diagram;
where the average gray level Gₐᵥₑ of the simulated magneto-optical image satisfies:

$${G}_{a v e} = \frac{1}{M \times N} {\sum }_{i = 1}^{M} {\sum }_{j = 1}^{N} I ( i , j ) ; \qquad ( 8 )$$

in the Formula (8), M and N denote the height and the width of the simulated magneto-optical image, respectively, and I(i, j) denotes the gray level of the pixel point (i, j);

$${G}_{ma x} = {max}_{1 \leq i \leq M , 1 \leq j \leq N} I ( i , j ) ; \qquad ( 9 )$$

the maximum gray level Gₘₐₓ of the simulated magneto-optical image satisfies:

$${G}_{m i n} = {min}_{1 \leq i \leq M , 1 \leq j \leq N} I ( i , j ) . \qquad ( 10 )$$

the minimum gray level Gₘᵢₙ of the simulated magneto-optical image satisfies:

Thereafter, an evaluation function E is constructed; where the evaluation function E satisfies:

$$E = \frac{{G}_{ma x} - {G}_{m i n}}{{G}_{a v e}} . \qquad ( 11 )$$

The value of E under different variable conditions is calculated. When the value of E is the maximum, the value of each variable in the three-dimensional simulation model corresponding to the maximum E is the optimal value (when the value of each variable is the optimal value, the detection effect of the integrated magneto-optical imaging probe is the best).

The present disclosure provides an integrated magneto-optical imaging probe and a parameter self-adjusting method thereof, where the parameter self-adjusting method includes the following steps: Step 1, obtaining a maximum leakage magnetic field intensity at the defect of a workpiece to be tested; Step 2, constructing a three-dimensional simulation model of the integrated magneto-optical imaging probe; Step 3, setting an optical physical field for a geometric structure of each part of the three-dimensional simulation model constructed in Step 2; Step 4, performing differential meshing on the three-dimensional simulation model processed in Step 3; and Step 5, setting scanning parameters for the three-dimensional simulation model processed in Step 4, and calculating a value of each variable in the three-dimensional simulation model; and drawing a simulated magneto-optical image.

The integrated magneto-optical imaging probe with the above technical features and the parameter self-adjusting method thereof have a vertical “projection-collection” optical path and a smaller sensing gap, and therefore, have a higher defect imaging definition and an integrated layout of device. At the same time, the present disclosure further provides a parameter self-adjusting method of a probe, which can adapt to detection requirements of diversified working conditions. Compared with the prior art, the technical solution of the present disclosure at least has the following technical advantages.
(1) The device structure has a higher integration and less out-of-focus phenomenon, which can effectively improve the definition of defect detection imaging.
(2) The device makes up the deficiency of experiment-based parameter adjustment in the prior art, improves applicability of the integrated magneto-optical imaging probe, and allows the integrated magneto-optical imaging probe to adapt to different working conditions through precise parameter adjustment.

The above is only the specific embodiment of the present disclosure, but the protection scope of the present disclosure is not limited thereto. Any changes or substitutions conceivable to those skilled in the art within the technical scope disclosed by the present disclosure should be covered within the protection scope of the present disclosure. Therefore, the protection scope of the present disclosure should be based on the protection scope of the claims.

What is claimed is:

1. A parameter self-adjusting method of an integrated magneto-optical imaging probe, which comprises a linearly polarized light emitting unit, a linearly polarized light modulation unit, a linearly polarized light imaging unit, and a clamping mechanism;
the clamping mechanism comprising an inner shell and an outer shell; wherein a linearly polarized light path is formed between the inner shell and the outer shell;
the linearly polarized light emitting unit comprising a light-emitting diode (LED) light source, a light guide plate, and a polarizer; wherein the LED light source is fixedly installed on a side wall of the inner shell; the light guide plate is fixedly installed inside the inner shell, and is configured to modulate light output by the LED light source into parallel light in a horizontal direction; and the polarizer is fixedly installed inside the inner shell and is arranged in a direction perpendicular to the parallel light, and is configured to modulate the parallel light into linearly polarize light;
the linearly polarized light modulation unit comprising a magneto-optical sensing module, a beam splitter, a silicon steel yoke, and a neodymium magnet; wherein the magneto-optical sensing module is fixedly installed inside the inner shell directly below the linearly polarized light path; the beam splitter is fixedly installed inside the inner shell and is configured to reflect the linearly polarized light modulated by the polarizer to a position of the magneto-optical sensing module; and the neodymium magnet and the silicon steel yoke are sequentially arranged and installed on a periphery of the linearly polarized light path to form a closed magnetic field loop; and
the linearly polarized light imaging unit comprising a camera, an analyzer, a camera driving board, and a Lemo connector; wherein the analyzer is fixedly installed on a top of the outer shell directly above the linearly polarized light path, and is configured to receive the linearly polarized light modulated by a leakage magnetic field; the camera, the camera driving board, and the Lemo connector are sequentially connected with the analyzer to convert an optical signal captured by the analyzer into an electrical signal and transmit the electrical signal to an external display device;
the method comprising:
step 1, obtaining a maximum leakage magnetic field intensity at a defect of a workpiece to be tested, which comprises:
placing the integrated magneto-optical imaging probe directly above the defect of the workpiece to be tested to excite the leakage magnetic field; and
using a Tesla meter to measure the maximum leakage magnetic field intensity B at the defect of the workpiece to be tested;
step 2, constructing a three-dimensional simulation model of the integrated magneto-optical imaging probe;
step 3, setting an optical physical field for a geometric structure of each part of the three-dimensional simulation model constructed in step 2;
step 4, performing differential meshing on the three-dimensional simulation model processed in step 3;
step 5, setting scanning parameters for the three-dimensional simulation model processed in step 4, and calculating a value of each variable in the three-dimensional simulation model; and drawing a simulated magneto-optical image; and
step 6, analyzing the simulated magneto-optical image obtained in step 5, and determining an optimal value of each variable in the three-dimensional simulation model.

2. The parameter self-adjusting method of the integrated magneto-optical imaging probe according to claim 1, wherein the step 2 comprising:
using a COMSOL model builder to construct the three-dimensional simulation model of the integrated magneto-optical imaging probe, wherein the three-dimensional simulation model constructed at least comprises simulation of geometrically simplified structures of the LED light source, the polarizer, a magneto-optical film, a mirror plating, the beam splitter, the camera, the analyzer, and a light blocking surface.

3. The parameter self-adjusting method of the integrated magneto-optical imaging probe according to claim 1, wherein the step 3 comprising:
setting the LED light source to emit uniform unpolarized light based on a mesh unit, in which a light source power set to W and an emitted light intensity I₀ satisfy:
$${I}_{0} = \frac{W}{l \times b} ; \qquad ( 1 )$$
in formula (1), l and b are a length and a width of a light emitting surface of the LED light source, respectively;
setting the polarizer, the magneto-optical film, and the analyzer as linear polarizers, wherein a transmission axis of the polarizer is defined as vₚ=(vₚₓ, v_{py}, v_{pz})=(cₚ, cₚ tan γ, 0) (2);
in formula (2), vₚ is a direction vector of the transmission axis of the polarizer, vₚₓ, v_{py}, and v_{pz} are projections of vₚ on an x-axis, a y-axis, and a z-axis, respectively, cₚ is a constant, and γ is an included angle between vₚ and a horizontal direction; and after the parallel light passes through the polarizer, a light intensity of the parallel light becomes I₀/2;
a deflection angle θ at which the linearly polarized light deflects when passing through the magneto-optical film satisfies: θ=VBT (3);
in formula (3), Vis Verdet constant, and Tis a thickness of the magneto-optical film;
a transmission axis of the magneto-optical film is defined as
$${v}_{m} = ( {v}_{m x} , {v}_{m y} , {v}_{m z} ) = ( {c}_{m} , {c}_{m} tan ( γ + θ ) , 0 ) = ( {c}_{m} , {c}_{m} tan ( γ + VBT ) , 0 ) ; \qquad ( 4 )$$
in formula (4), vₘ is a direction vector of the transmission axis of the magneto-optical film, vₘₓ, v_{my}, and v_{mz} are projections of vₘ on the x-axis, the y-axis, and the z-axis, respectively, and cₘ is a constant; and
a transmission axis of the analyzer (11) is defined as
$${v}_{d} = ( {v}_{dx} , {v}_{dy} , {v}_{d z} ) = ( {c}_{d} , {c}_{d} tan ( γ + VBT + α ) , 0 ) ; \qquad ( 5 )$$
in formula (5), v_{d} is a direction vector of the transmission axis of the analyzer, v_{dx}, v_{dy}, and v_{dz} are projections of v_{d} on the x-axis, the y-axis, and the z-axis, respectively, and c_{d} is a constant; and
setting a reflectivity of the beam splitter to r, setting a transmissivity of the beam splitter to 1−r, setting a reflection coefficient of the mirror plating to 1, and a light intensity I_{D} of the linearly polarized light after passing through the analyzer satisfying:
$${I}_{D} = 0.5 r ( 1 - r ) {I}_{0} {cos}^{2} ( VBT + α ) = 0.5 r ( 1 - r ) \frac{W}{l \times b} {cos}^{2} ( VBT + α ) . \qquad ( 6 )$$

4. The parameter self-adjusting method of the integrated magneto-optical imaging probe according to claim 1, wherein the step 6 comprising:
calculating an average gray level Gₐᵥₑ of the simulated magneto-optical image, a maximum gray level Gₘₐₓ of the simulated magneto-optical image, and a minimum gray level Gₘᵢₙ of the simulated magneto-optical diagram;
wherein the average gray level Gₐᵥₑ of the simulated magneto-optical image satisfies:
$${G}_{a v e} = \frac{1}{M \times N} {\sum }_{i = 1}^{M} {\sum }_{j = 1}^{N} I ( i , j ) ; \qquad ( 8 )$$
in formula (8), M and N denote height and width of the simulated magneto-optical image, respectively, and I(i, j) denotes a gray level of a pixel point (i, j);
the maximum gray level Gₘₐₓ of the simulated magneto-optical image satisfies:
$${G}_{ma x} = {max}_{1 \leq i \leq M , 1 \leq j \leq N} I ( i , j ) ; \qquad ( 9 )$$
and
the minimum gray level Gₘᵢₙ of the simulated magneto-optical image satisfies:
$${G}_{m i n} = {min}_{1 \leq i \leq M , 1 \leq j \leq N} I ( i , j ) ; \qquad ( 10 )$$
constructing an evaluation function E; wherein the evaluation function E satisfies:
$$E = \frac{{G}_{m ax} - {G}_{m i n}}{{G}_{a v e}} ; \qquad ( 11 )$$
and
calculating a value of E under different variable conditions; in which when the value of E is a maximum, a value of each variable in the three-dimensional simulation model corresponding to the maximum is the optimal value.
